(19) United States
(12) Patent Application Publication
(10) Pub. No.: US 2016/0131587 A1
(43) Pub. Date: May 12, 2016

(54) Method and Apparatus for Monitoring Pulsed Plasma Processes

(71) Applicant: Verity Instruments, Inc., Carrollton, TX (US)

(72) Inventors: Mark Anthony Meloni, Carrollton, TX (US); Andrew Weeks Kueny, Carrollton, TX (US); Larry Arlos Bullock, Carrollton, TX (US); Tim Charles Michals, Carrollton, TX (US); Christopher David Pylant, Carrollton, TX (US)

(21) Appl. No.: 14/509,038

(22) Filed: Oct. 7, 2014

(51) Int. Cl. G01N 21/66; H01J 37/32

(52) U.S. Cl. CPC G01N 21/66; H01J 37/321; H01J 37/32174; H01J 37/32137; G01N 2201/12

(57) ABSTRACT

Emitted light from a pulsed plasma system is detected, amplified and digitized over a plurality of pulse modulation cycles to produce a digitized signal over the plurality of RF modulation periods, each of which contains an amount of random intensity variations. The individual signal periods are then mathematically combined to produce a stable local reference waveform signal that has decreased random intensity variations. One mechanism for creating a stable local reference waveform signal is by subdividing each of the individual signal periods into a plurality of subunits and the mathematically averaging the respective subunits within the modulation period to produce the stable local reference waveform signal for the modulation period. The stable local reference waveform signal can then be compared to other instantaneous waveform signals from the pulsed plasma system, or waveform parameters can be derived using various signal processing techniques such as Fourier analysis.

### CROSS-REFERENCE TO RELATED APPLICATIONS

The present application is related to and claims priority from co-pending U.S. Provisional Patent Application Ser. No.: 62/043,215, which is assigned to the assignee of the present invention. The above identified application is incorporated by reference herein in its entirety.

### BACKGROUND OF THE INVENTION

The present invention relates generally to optical emission spectroscopy. More particularly, the present invention relates to a system, method and software program product for monitoring and analyzing the optical emission from a pulsed plasma wafer processing system.

Optical emission spectroscopy (OES) is widely used in the semiconductor industry for monitoring the state of a wafer process within a reactor by using the plasma light emission generated within the reactor. While OES techniques may vary with the particular application and process, typically the light emission intensities are monitored at one or more predetermined wavelengths. Depending on the process, various algorithms may be employed for deriving trend parameters from the light intensities that are useful in assessing the state of the semiconductor process and the processed wafer, detecting faults associated with the process, reactor or other equipment and even the condition of interior surfaces of the plasma reactor.

With specific regard to monitoring and evaluating the state of a plasma process within a reactor, FIG. 1 illustrates a typical process 100 for employing OES to monitor and/or control the state of a plasma process within a plasma reactor. The present method is greatly simplified for expedience. The process typically begins by determining which wavelengths will yield useful results for the particular production process being implemented (step 110), often one or more optical filters will be disposed along the light path from the reactor viewport for filtering unwanted light wavelengths. Light is detected from the plasma at the viewport (step 120), post detection and conversion to electrical signals, the signals are typically amplified and then digitized (step 130), and passed to a signal processor. The signal processor employs one of more algorithms that is/are specific to the particular production process (step 140). The selection of the proper algorithm, as well as variable values, for the particular process is imperative to achieving a valid result. Without being too specific, the algorithm analyzes emission intensity signals at the predetermined wavelength(s) and determines trend parameters that relate to the state of the process and can be used to access that state, for instance end point detection, etch depth, etc. (step 150). The results are output (step 160) and then used for monitoring and/or modifying the production process occurring within the plasma reactor (step 170).

The generic method discussed above with regard to FIG. 1 is useful in monitoring/evaluating many different processes using both steady state and pulsed plasma reactors. However, the light emission from a pulsed plasma generated by an RF plasma reactor may also exhibit light variations at time scales comparable to the RF modulation period of the pulsed plasma that are not detectable using conventional OES techniques. Hence, it is advantageous to evaluate the light emission intensities at various wavelengths, but at time scales comparable to the RF modulation period. For clarity, the RF modulation period is not the primary RF frequency, typically 2-60 MHz, but the modulation of this primary signal at a rate much less than the primary RF frequency; e.g., 1000 Hz. This information from a pulsed plasma can be used instead of or to supplement conventional OES results. However, due to the high degree of randomness of the intensity values within any single RF modulation period, what is needed is a mechanism for creating a stable local reference waveform signal over the modulation period for, among other things, a digital representation of the local reference waveform signal over the modulation period, Fourier analysis for determining waveform signal parameters in the frequency domain and for comparing to an instantaneous signal for identifying faults and other changes in the instantaneous signal.

### BRIEF SUMMARY OF THE INVENTION

The present invention is directed to a system, method and software product for monitoring a pulsed plasma wafer processing system. Emitted light from a pulsed plasma system is detected, amplified and digitized over a plurality of pulsed modulation cycles to produce a digital signal over the plurality of RF modulation periods, each of which contains an amount of random intensity variation. Portions of the digitized signal corresponding to the individual RF modulation periods are then mathematically combined to produce a stable local reference waveform signal that has decreased random intensity variation. One mechanism for creating a stable local reference waveform signal is by subdividing each of the individual RF modulation periods into a plurality of subunits and then mathematically averaging the temporally corresponding subunits within the plurality of RF modulation periods to produce the stable local reference waveform signal for the RF modulation period. The stable local reference waveform signal can then be compared to instantaneous waveform signals from the pulsed plasma system, or waveform parameters can be derived from it using various signal processing techniques such as Fourier analysis.

### BRIEF DESCRIPTION OF THE SEVERAL VIEWS OF THE DRAWINGS

The novel features believed characteristic of the present invention are set forth in the appended claims. The invention itself, however, as well as a preferred mode of use, further objectives and advantages thereof, will be best understood by reference to the following detailed description of an illustrative embodiment when read in conjunction with the accompanying drawings wherein:

FIG. 1 illustrates a typical process 100 for employing OES to monitor and/or control the state of a plasma process within a plasma reactor;

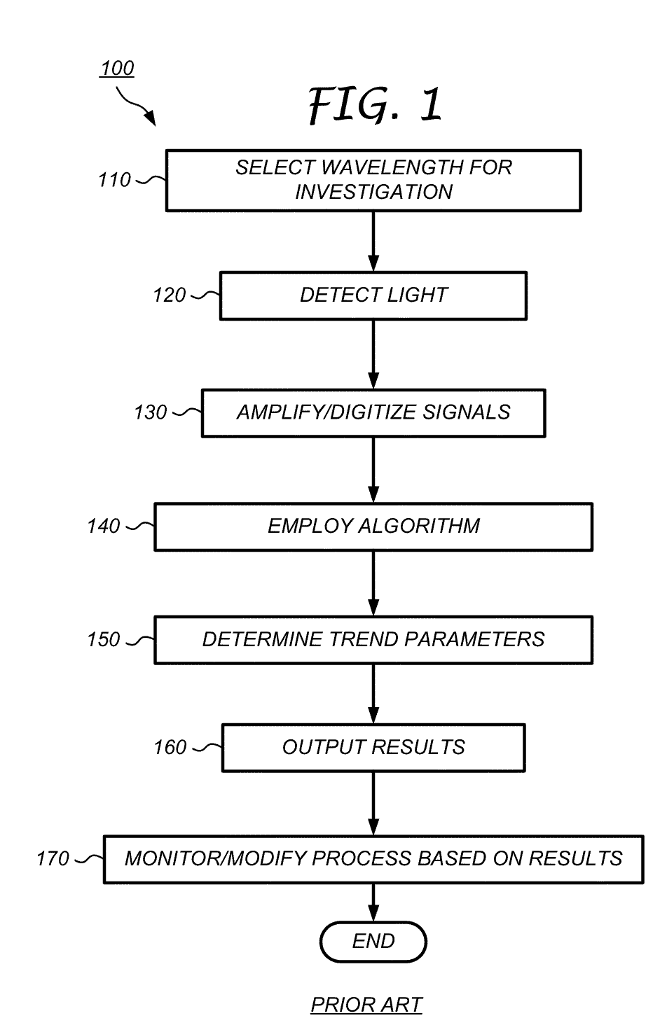

FIG. 2 shows a simplified block diagram of a pulsed plasma monitoring system 200 in accordance with an exemplary embodiment of the present invention;

FIG. 3 is a flowchart illustrating a process for monitoring/analyzing light emission of a pulsed plasma monitoring system in accordance with an exemplary embodiment of the present invention;

FIG. 4 shows a flowchart of a more detailed process 400 for operating a pulsed plasma monitoring system in accordance with one exemplary embodiment of the present invention;

FIGS. 5A and 5B depict a flowchart that illustrates one method for mathematically averaging multiple cycles of light emission from a pulsed plasma reactor system over the RF modulation period in accordance with one exemplary embodiment of the present invention;

FIG. 6 shows a plot 600 of a sampled and digitized optical signal 610 captured by an embodiment of the current invention;

FIG. 7 shows a plot 700 of a calculated average waveform 710, in accordance with various embodiments of the present invention and an instantaneous waveform 720, indicated by a solid line;

FIGS. 8A and 8B show front and rear views respectively of an embodiment of a pulsed plasma monitoring system 800 of the present invention.

### DETAILED DESCRIPTION OF THE INVENTION

### Element Reference Number Designations

200: Pulsed plasma monitoring system
210: Plasma reactor
220: Wafer
230: Plasma
235: Emitted light
240: Optical filter
250: Optical Detector
260: Signal Digitizer
270: Signal Processor
280: Output
800: Pulsed plasma monitoring system
810: Separable processor subsystem
820: Detector subsystem
830: Interface cable
840: Fiber optic adapter
850: Display
860: Power switch
870: Power connector
880: Communication interface

In the following description, reference is made to the accompanying drawings that form a part hereof, and in which is shown by way of illustration, specific embodiments in which the invention may be practiced. These embodiments are described in sufficient detail to enable those skilled in the art to practice the invention, and it is to be understood that other embodiments may be utilized. It is also to be understood that structural, procedural and system changes may be made without departing from the spirit and scope of the present invention. The following description is, therefore, not to be taken in a limiting sense. For clarity of exposition, like features shown in the accompanying drawings are indicated with like reference numerals and similar features as shown in alternate embodiments in the drawings are indicated with similar reference numerals.

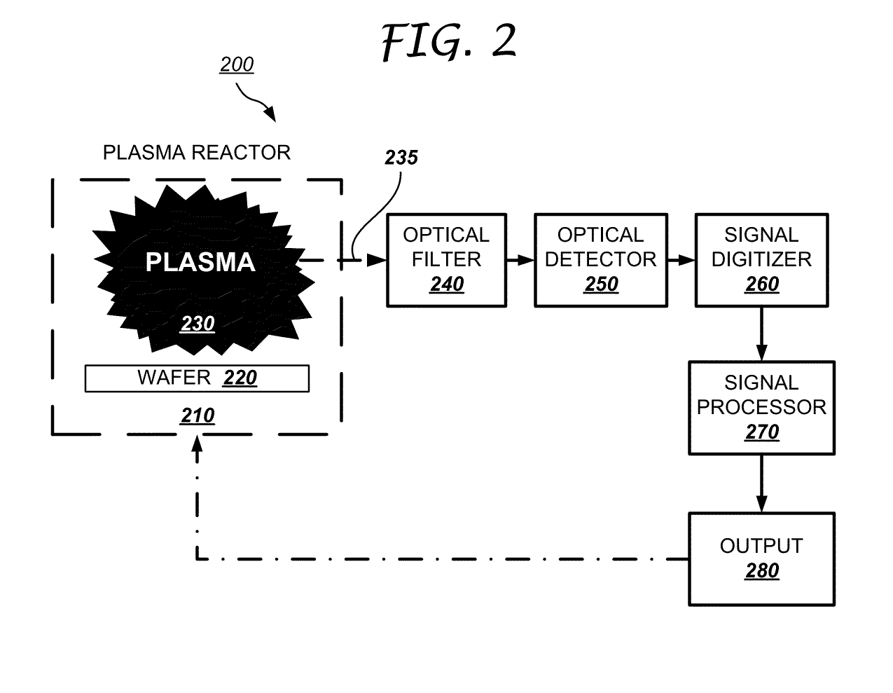

FIG. 2 shows a simplified block diagram of pulsed plasma monitoring system 200. Plasma reactor 210 operates in a pulsed RF power mode to modify wafer 220. This means that a periodic modulation is applied to the RF power. The RF power of reactor 210 may, for example, be switched between fully on and fully off states at 50% duty cycle at 1000 Hz. The response of the plasma to this modulation is complicated. Its excitation state will oscillate with the same period as the RF power modulation, but the details will be different. For example, whereas the RF power may switch effectively instantaneously between the on and off states, the degree of excitation may change gradually between two intermediate states with different characteristic rise and fall times. Understanding how the plasma reacts to the RF modulation is important for getting the best performance out of the reactor. Plasma 230 excited within reactor 210 produces light which is available for viewing via an optical viewport (not shown). Monitoring the time dependence of the intensity of the emitted light gives insight into the excitation response of the plasma.

The plasma state in a reactor is constantly changing and the changes on different timescales may be considered separately. The shortest time scale is on the order of a single RF cycle. This is typically in the range of 10 nanoseconds to 1 microsecond and corresponds to the primary RF frequency range of approximately 1-100 MHz A second time scale concerns changes that happen slowly compared to the RF cycle but are not slow compared to the RF modulation period. This is typically in the range of 0.1 milliseconds to 10 milliseconds. A third time scale concerns changes which are slow compared to the RF modulation period, but not compared to the duration of the process step. This is typically in the range of 1-100 seconds. The response of the plasma to the RF modulation, which is the subject of interest, occurs on the second timescale. A quantity of interest is the light intensity as a function of time over the time interval of a single period of the RF modulation. This quantity is expected to be nearly the same when measured on successive periods of the RF modulation, and change only on the third timescale. Should it happen that it changes significantly (a predeterminable quantity) from one RF modulation period to the next, this would be regarded as evidence of abnormal operation, and therefore detection of occurrences of this type is also of interest.

This description describes an apparatus and method to provide a digital record of the light emitted from the plasma, optimized to convey this information to the operator and/or control subsystem of the reactor. This record is updated at a reporting rate which is slow compared to the first and second time scales, but fast compared to the third time scale. The information conveyed is in three parts. The first part is a digital representation of the optical intensity as a function of time over the time interval of a single period of the RF modulation characteristic of a typical RF cycle at the time the report is made. The second part is fault report, sent in the event that the optical signal during any single RF cycle was significantly different from the typical one being reported. Should that happen, the fault report is a digital representation of the optical intensity over an interval of multiple RF modulation periods which includes the time when the difference occurred. Finally, the third part of the report is a list of waveform parameters, e.g., the Fourier amplitudes and phases of the fundamental and higher harmonics of the optical signal in the frequency domain. Additional portions of the information may include details of the types and timing of detected faults. Emitted light 235 is received by optical detector 250 and may be coupled from the viewport to optical detector 250 via an optical fiber (not shown). Optionally, optical filter 240 may be placed between the viewport and optical detector 250 to select specific wavelengths of light of interest. Optical detector 250 may be, for example, a silicon PIN photodiode responsive to approximately 350-1100 nm.

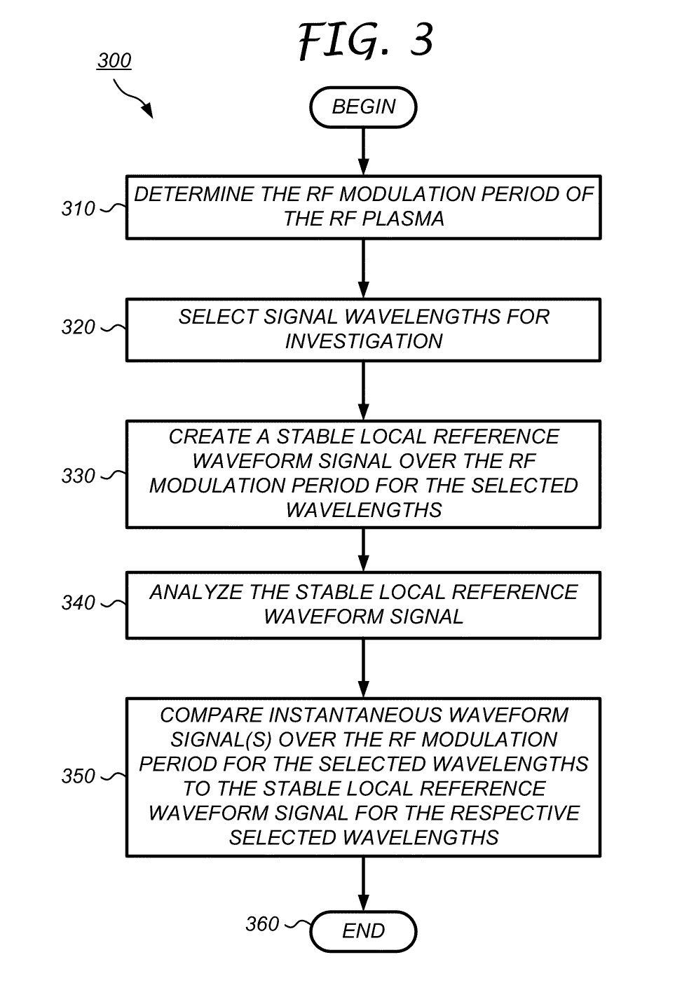

Electrical signals from optical detector 250 may be amplified and sent to signal digitizer 260 for conversion to digital signals. Signal digitizer 260 samples the modulated optical signal converted by optical detector 250 to produce a set of measured values which, typically, include more than a single period of RF modulation. The measured values may then be transferred to processor 270 for processing such as described in association with FIGS. 3, 4, 5A and 5B below. Processor 270 may also communicate by output system 280 to convey processed data back to reactor 210 for monitoring and/or control of reactor 210.

Signal processor 270 receives the digital signals and processes the digital signals to determine, for example, 1) an average waveform of the digitized pulsed optical output; 2) faults which are signals that differ from the average waveform, depart from intended plasma frequency, signal saturation, etc., some faults do not depend on average waveform; and 3) Fourier and/or spectral analysis parameters of the average waveform.

FIG. 3 is a flowchart illustrating process 300 for monitoring/analyzing light emission within the RF modulation period of a pulsed plasma system in accordance with an exemplary embodiment of the present invention. The process begins by determining the period (T) of the RF pulsed plasma modulation (step 310). The period T is usually readily known and available to the operator or system controller, however, it may also be determined on the fly using various analysis techniques. Having an accurate estimate of the period is necessary as both the digitizing/sampling and waveform creation algorithms make use of this information. Next, optionally the light wavelengths of interest for the present production process are identified (step 320) and an optional optical filter may be installed. When optically filtered, the selected wavelengths will be the only wavelengths sampled and sent to the signal processor for, among other things, conversion to the stable local reference waveform signal. With the RF modulation period known, a stable local reference waveform signal can be created for the RF modulation period for the selected wavelengths (step 330).

The inventors of the present invention have discovered that any single instantaneous waveform signal contains a significant amount of random intensity variation or noise. This noise makes comparing any single instantaneous waveform signal to any other single instantaneous waveform signal troublesome as the result may contain a large amount of random error. Furthermore, evaluating any single instantaneous waveform signal for waveform parameters, especially at frequencies higher than the fundamental frequency of the RF modulation, is likewise unreliable because of the possibility of noise in the signals. Therefore, what is needed is a local reference waveform signal for the RF modulation period. In accordance with one exemplary embodiment of the present invention, a local reference waveform signal is created as a compilation of signals from a substantially high number of RF modulation periods, in so doing the random variations of light intensity are reduced. The compilation of signals may be achieved by different mechanisms, one of which is by averaging a plurality of waveform signals over the RF modulation period.

Additionally, the local reference waveform signal should be of sufficiently high temporal and digital resolution that frequencies much higher than the fundamental frequency of the RF modulation period can be resolved. Therefore, a sufficiently high number of samples should be digitized within each period. For example, the captured signal may be sampled, during digital conversion, at a temporal resolution of at least 100 times the frequency of the signal modulation, ideally between 100× and 200× of the frequency of the RF modulation.

The stable local reference waveform signal can be output and/or used for other analysis, for example to determine and evaluate waveform parameters (step 340), such as by Fourier analysis. Additionally, the stable local reference waveform signal provides a baseline signal from which instantaneous waveform signals may be compared (step 350) such as for fault detection. The results of the forgoing analyses or comparison may then be output for use in the process (step 360).

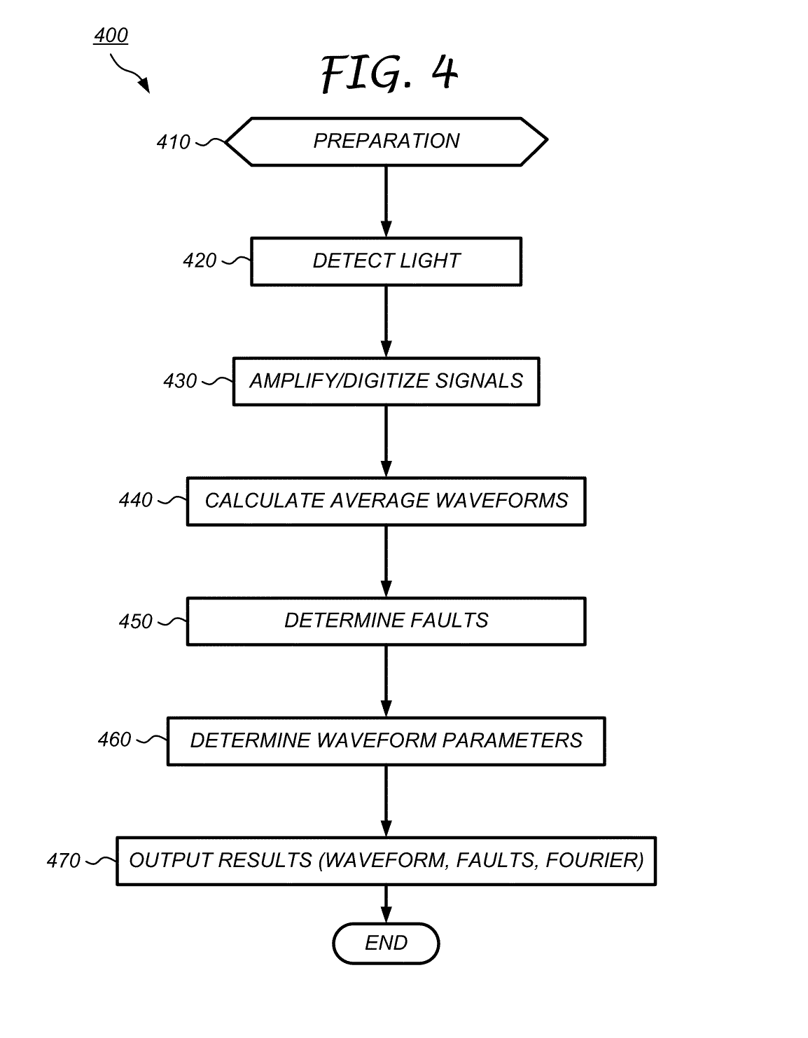

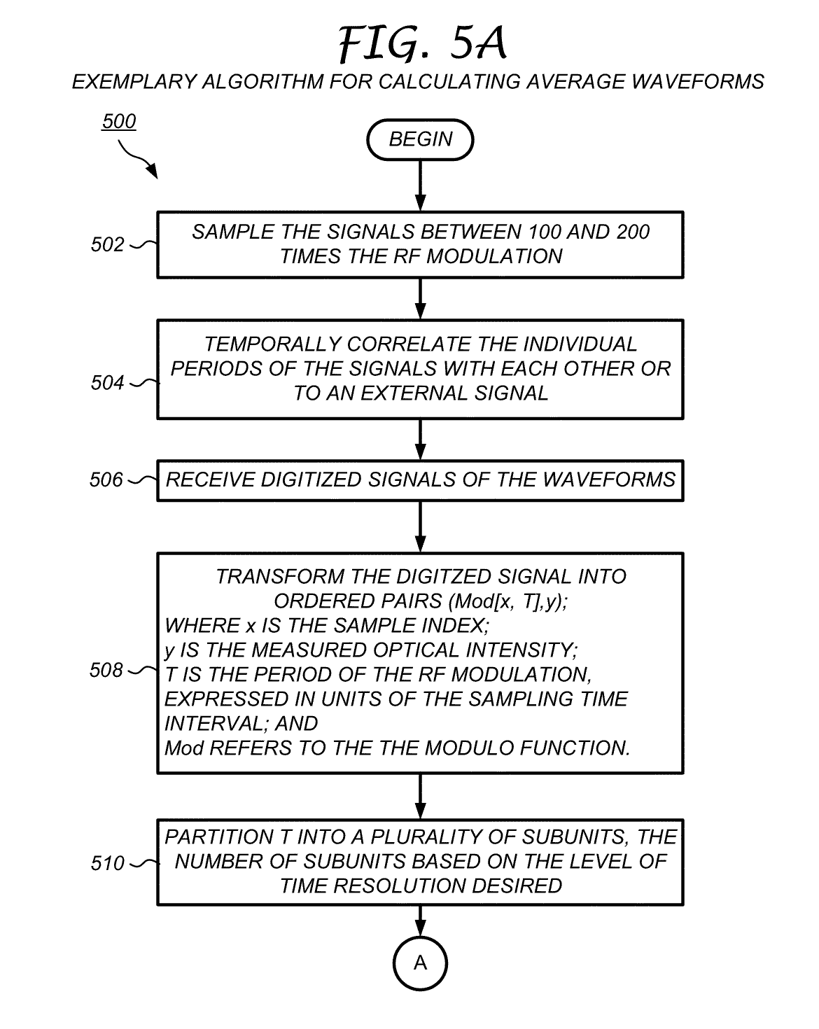

FIG. 4 shows a flowchart of a more detailed process 400 for operating the pulsed plasma monitoring system in accordance with one exemplary embodiment of the present invention. Process 400 begins with preparation step 410 wherein any required or desired setup is performed, for example, connection of optical fibers, transfer of operating parameters such as sampling rate and the selection of an optical filter. Next, process 400 advances to step 420 wherein light emitted from the plasma is detected and converted into electrical signals. Subsequently, in step 430 the electrical signals may be amplified and digitized by well-known subsystems over multiple periods of the RF modulation. These multiple periods may be mathematically averaged to produce an average waveform of the modulated signal in step 440 as discussed herein with respected to FIGS. 5 below. The average waveform provides a stable temporally local reference signal for the determination, comparison, and extraction of further signal features. This is in contrast to the general description of the prior art where limited portions of modulated signals are digitized and collected.

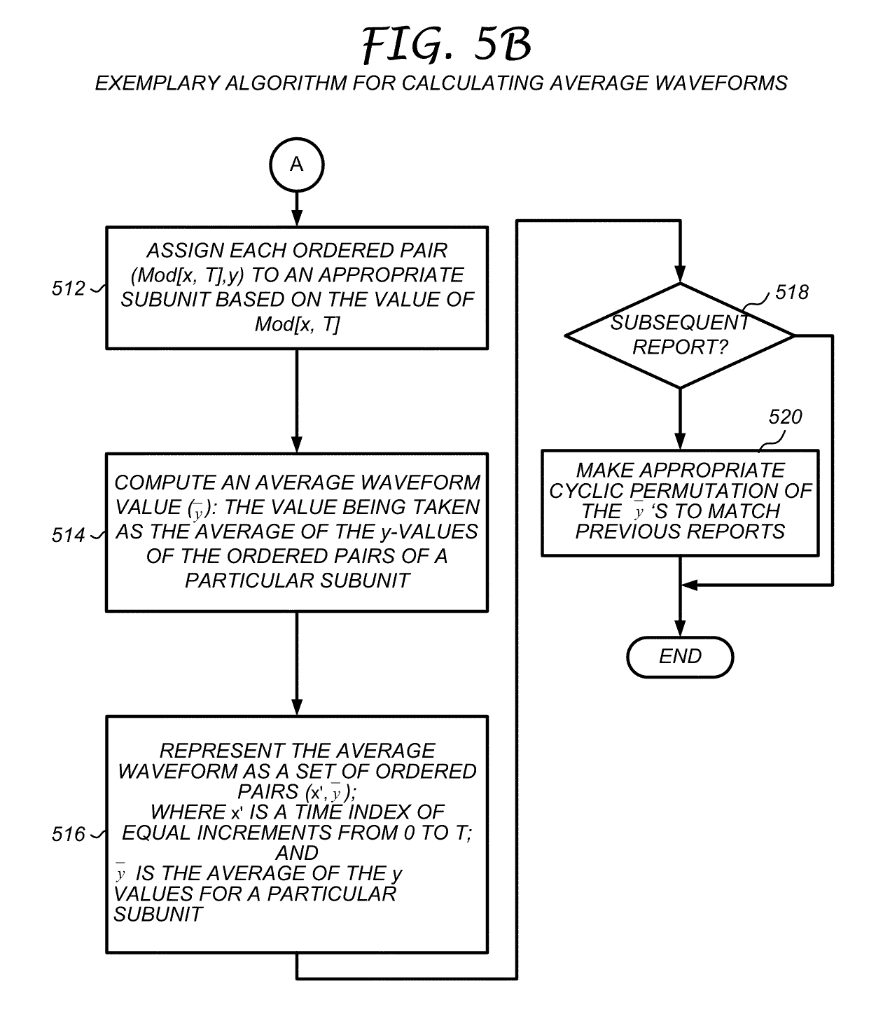

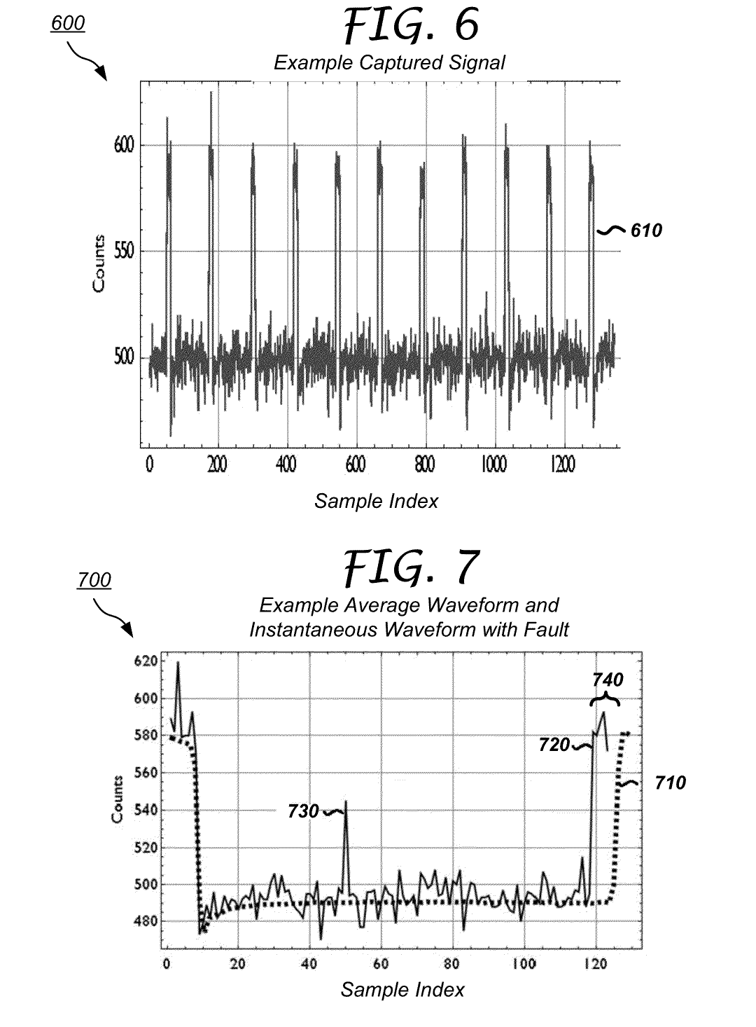

During step 450 comparisons of the average waveform with any of the other individual periods or samples of the previously captured samples of the modulated optical signal are used to detect faults. A fault may be generally defined as unexpected variation above a predefined threshold of one or more sampled values of any individual waveform when compared to the average waveform. Examples of sampled data, an average waveform and a detected fault are discussed below in association with FIGS. 6 and 7.

Next, in step 460 waveform parameters may be calculated. These parameters may be determined from the average waveform and/or the sampled signals by Fourier signal processing techniques to provide values such as the frequencies, magnitudes and relative phases of the harmonics of the captured waveform and the duty cycle of the waveform. Additionally and/or optionally, any waveform parameter such as defined in The IEEE Standard on Transitions, Pulses, and Related Waveforms, Std-181-2003, included herein by reference, may be determined. These parameters include, but are not limited to, state levels, state boundaries, reference levels, waveform aberrations, transition times, rise times, fall times and overshoot/undershoot conditions. In step 470, any determined faults and calculated values may be output to the pulsed plasma reactor or other system for control modification, archiving and/or review. Process 400 ends wherein any final operations are performed. Such operations may include saving and closing of files, stopping of sampling and termination of any outputs to external systems.

Creating a stable temporally local reference signal for further evaluation of the signal is an important feature of the presently described invention that is needed for pulsed plasma processes but not for conventional OES techniques. As mentioned above, one mechanism for realizing a stable temporally local reference signal as described in step 330 of FIG. 3, is by mathematically averaging multiple cycles over the RF modulation period of the modulated signal as further discussed with reference to step 440 of FIG. 4. FIGS. 5A and 5B depict a flowchart that illustrates one method for mathematically averaging multiple periods of light emission from a pulsed plasma reactor system over the RF modulation period in accordance with one exemplary embodiment of the present invention. Steps 502 through 506 are preparatory functions for preparing the signals for averaging. Initially, the optical emission from the pulsed plasma are amplified and digitized as necessary (as in step 430 above), the signals being sampled between 100 and 200 times the RF modulation rate (step 502).

FIG. 6 shows a plot 600 of a sampled and digitized optical signal 610 captured by an embodiment of the current invention. Plot 600 shows approximately 10 cycles of the captured signal 610. The signal is sampled at approximately 130× the frequency of the RF modulation. The sampling is preferably in the range of 100× to 200× that of the RF modulation rate to provide sufficient resolution for observing details and signal features at much higher frequencies than the fundamental frequency of the RF modulation. It should be understood that all elements of the system as described by the block diagram of FIG. 2 must support the appropriately wide bandwidth to permit the transfer of such higher frequency signals.

Returning to the description of FIGS. 5A and 5B, next, because the signals will be mathematically averaged over the RF modulation period, the individual periods of the digitized signals should be temporally correlated with each other or with an external signal such as a gating signal to the RF generator (step 504). Finally, the digitized signals of the waveforms are received at the signal processor (270 in FIG. 2) for averaging.

The average waveform can be constructed from the sampled digitized signal as follows: The ordered pairs (Mod[x, T],y) are computed, where x is the sample index, y is the measured optical intensity, T is the period of the RF modulation, expressed in units of the sampling time interval, and Mod refers to the modulo function (step 508). T is partitioned into a number of smaller subunits, the number being chosen to provide the desired level of time resolution in the digital representation of the average waveform (step 510). Each ordered pair (Mod[x, T], y) is assigned to the appropriate subunit based on the value of Mod[x, T] (step 512). The value of the average waveform in each subunit is taken to be the average of the y-values of the ordered pairs assigned to that subunit (step 514). The representation of the average waveform is now a set of ordered pairs (x′, y̅) where x′ is a time index that runs from 0 to T in equal sized steps, and y̅ is the average of the y values associated with that subunit (step 516). The starting point of the average waveform, when computed as described, depends on the point in the cycle where the sampled optical signal 610 begins. Unless this is synchronized with the RF generator, as described in step 504, this will vary, and the average waveform shown in FIG. 7 will be phase-shifted and not look the same in successive reports.

At this point, a plot of the average waveform may be typically displayed and updated in real time as the reactor is run, and this display would be difficult to interpret if the starting point changes several times per second. If the current report is successive to another report (step 518), the successive reports' average waveform can be transformed to look the same as the previous report(s) by making the appropriate cyclic permutation of the y̅'s in each one (step 520) effectively shifting the phase of the average waveform. This may be set, for example, to zero the phase of the fundamental frequency.

FIG. 7 shows a plot 700 of a calculated average waveform 710, indicated by a dashed line, and an instantaneous waveform 720, indicated by a solid line. This is the aforementioned digital representation of the typical optical intensity that comprises the first element of the information reported by the device, hereinafter referred to as the “average waveform.” Average waveform 710 is calculated, for example, from the captured signal 610 of FIG. 6 discussed above.

As noted previously, the average waveform provides a stable temporally local reference signal for the determination, comparison, and extraction of further signal features. As seen in FIG. 7, by comparing instantaneous waveform 720 with average waveform 710, two different faults are represented. The first fault is represented as fault 730 at sample index 50 and is considered a fault since it deviates approximately 60 counts from the expected average waveform value considering a predetermined fault detection threshold of 45 counts. A fault detection threshold may be defined by characterizing the peak-to-peak noise or other metrics of the average waveform. In the example for FIG. 7, the peak-to-peak noise level is approximately 30 counts and the fault detection threshold has been defined to be 1.5× the peak-to-peak noise level. Plot 700 includes a second fault in the form of a duty cycle variation between the average waveform and the instantaneous signal. After aligning the falling edges of instantaneous waveform 720 and average waveform 710, the duty cycle variation is readily observed by noting that the upward transition of the instantaneous waveform 720 occurs approximately six samples, represented as fault 740, prior to the upward transition of average waveform 710. Other types of faults and variations may also be detected.

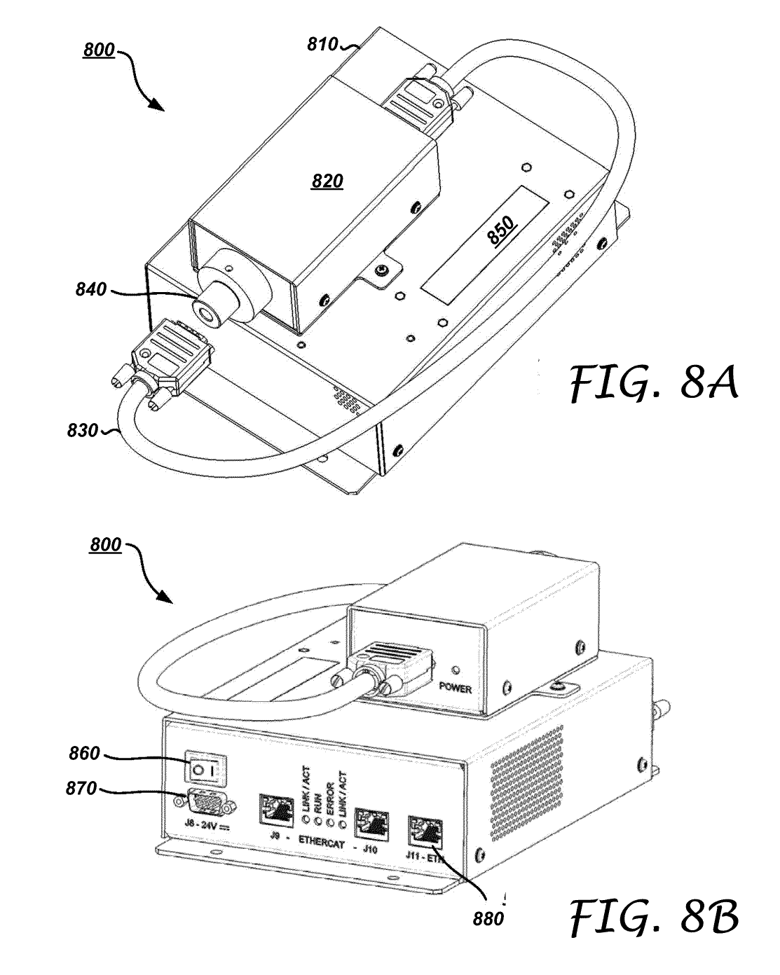

FIGS. 8A and 8B show front and rear views respectively of an embodiment of pulsed plasma monitoring system 800 of the present invention. System 800 may be built with a modular design including separable processor subsystem 810 and detector subsystem 820 connectable via interface cable 830. Modular design of system 800 permits relocation of individual subsystems to mitigate temperature, space, and other adverse issues. Detector subsystem 820 specifically includes fiber optic adapter 840 which may include mounting features for a fiber optic cable, an optical filter, and adjustment for optical signal levels. Display 850, such as an LCD display, may be integrated with processor subsystem 810 to permit operator viewing of output from system 800. Processor subsystem 810 may also integrate common features such as power switch 860, power connector 870, and communication interface 880. System 800 may be DC or AC powered and includes one or more communication interfaces such as Ethernet, EtherCAT, DeviceNET and/or RS232 permitting bidirectional control and communication to/from a plasma reactor or other systems.

As will be appreciated by one of skill in the art, the present invention may be embodied as a method, system, or computer program product. Accordingly, the present invention may take the form of an entirely hardware embodiment, an entirely software embodiment (including firmware, resident software, micro-code, etc.) or an embodiment combining software and hardware aspects all generally referred to herein as a “circuit” or “module.” Furthermore, the present invention may take the form of a computer program product on a computer-usable storage medium having computer-usable program code embodied in the medium.

Any suitable computer readable medium may be utilized. The computer-usable or computer-readable medium may be, for example but not limited to, an electronic, magnetic, optical, electromagnetic, infrared, or semiconductor system, apparatus, device, or propagation medium. More specific examples (a nonexhaustive list) of the computer-readable medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a transmission media such as those supporting the Internet or an intranet, or a magnetic storage device. Note that the computer-usable or computer-readable medium could even be paper or another suitable medium upon which the program is printed, as the program can be electronically captured, via, for instance, optical scanning of the paper or other medium, then compiled, interpreted, or otherwise processed in a suitable manner, if necessary, and then stored in a computer memory. In the context of this document, a computer-usable or computer-readable medium may be any medium that can contain, store, communicate, propagate, or transport the program for use by or in connection with the instruction execution system, apparatus, or device. The computer-usable medium may include a propagated data signal with the computer-usable program code embodied therewith, either in baseband or as part of a carrier wave. The computer usable program code may be transmitted using any appropriate medium, including but not limited to the Internet, wireline, optical fiber cable, RF, etc.

Moreover, the computer readable medium may include a carrier wave or a carrier signal as may be transmitted by a computer server including internets, extranets, intranets, world wide web, ftp location or other service that may broadcast, unicast or otherwise communicate an embodiment of the present invention. The various embodiments of the present invention may be stored together or distributed, either spatially or temporally across one or more devices.

Computer program code for carrying out operations of the present invention may be written in an object oriented programming language such as Java, Smalltalk or C++. However, the computer program code for carrying out operations of the present invention may also be written in conventional procedural programming languages, such as the “C” programming language. The program code may execute entirely on the user's computer, partly on the user's computer, as a stand-alone software package, partly on the user's computer and partly on a remote computer or entirely on the remote computer. In the latter scenario, the remote computer may be connected to the user's computer through a local area network (LAN) or a wide area network (WAN), or the connection may be made to an external computer (for example, through the Internet using an Internet Service Provider).

A data processing system suitable for storing and/or executing program code may include at least one processor coupled directly or indirectly to memory elements through a system bus. The memory elements can include local memory employed during actual execution of the program code, bulk storage, and cache memories which provide temporary storage of at least some program code in order to reduce the number of times code must be retrieved from bulk storage during execution.

The exemplary embodiments described above were selected and described in order to best explain the principles of the invention and the practical application, and to enable others of ordinary skill in the art to understand the invention for various embodiments with various modifications as are suited to the particular use contemplated. The particular embodiments described above are in no way intended to limit the scope of the present invention as it may be practiced in a variety of variations and environments without departing from the scope and intent of the invention. Thus, the present invention is not intended to be limited to the embodiments shown, but is to be accorded the widest scope consistent with the principles and features described herein.

The flowchart and block diagrams in the Figures illustrate the architecture, functionality, and operation of possible implementations of systems, methods and computer program products according to various embodiments of the present invention. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems which perform the specified functions or acts, or combinations of special purpose hardware and computer instructions.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

What is claimed is:

1. A method for monitoring a pulsed plasma processing system, said plasma processing system comprising at least a plasma reactor and an RF plasma generator for exciting a plasma at a predetermined pulsed frequency to produce a pulsed plasma at a predetermined pulsed modulation period within the plasma reactor, the method comprising:
detecting light generated by the pulsed plasma processing system;
sampling the detected light over a plurality of cycles of a modulation period to provide a digitized signal;
deriving a local reference waveform signal for the modulation period from the plurality of cycles of the digitized signal; and
analyzing the local reference waveform signal for the modulation period to derive one of a fault condition of the pulsed plasma processing system, a process condition of the pulsed plasma processing system, and waveform parameter of the local reference waveform signal.

2. The method of claim 1, wherein deriving the local reference waveform signal for the modulation period from the plurality of cycles of the digitized signal further comprises:
partitioning each modulation period of the digitized signal into a plurality of subunits of waveform intensity values, a number of subunits based on a predetermined time resolution;
computing an average waveform intensity value for each of the plurality of subunits from the plurality of subunits of waveform intensity values; and
compiling each of the average waveform intensity values from the respective subunits into the local reference waveform signal for the modulation period.

3. The method of claim 2, further comprising:
temporally correlating each of the plurality of cycles of the digitized signal.

4. The method of claim 3, wherein each of the plurality of cycles of the modulation period of the digitized signal is temporally correlated to one of another cycle of the modulation period of the digitized signal and the predetermined pulsed modulation period produced from the RF plasma generator.

5. The method of claim 1 further comprises:
detecting instantaneous light generated by the pulsed plasma processing system;
sampling the instantaneous detected light to provide a digitized instantaneous waveform signal; and
wherein analyzing further comprises comparing the digitized instantaneous waveform signal to the local reference waveform signal.

6. The method of claim 1, further comprises:
sampling the detected light above 100-times the predetermined frequency of the RF modulation; and
analyzing the local reference waveform signal by applying a Fourier analysis to determine at least one waveform signal parameter in the frequency domain, wherein the waveform signal parameter is one of duty cycle, Fourier component amplitudes, fundamental frequency and harmonic frequency and phase parameters.

7. The method of claim 6, further comprising transferring at least one of the digitized signal, the local reference waveform signal, and the waveform signal parameter to the pulsed plasma processing system.

8. The method of claim 7, further comprising modifying operation of the pulsed plasma processing system based upon at least one of the digitized signal, the local reference waveform signal and at least one waveform signal parameter thereof.

9. The method of claim 5, further comprising transferring at least one of the digitized signal and the local reference waveform signal to the pulsed plasma processing system.

10. The method of claim 9, further comprising modifying operation of the pulsed plasma processing system based upon at least one of the digitized signal, the local reference waveform signal and the comparison of the digitized instantaneous waveform signal to the local reference waveform signal.

11. A pulsed plasma processing system, comprising
a plasma reactor;
an RF plasma generator for exciting a plasma at a predetermined frequency to produce a pulsed plasma at predetermined RF modulation period within the plasma reactor;
a reactor control system for controlling the plasma reactor and the RF plasma generator;
a light detector for detecting light generated by the pulsed plasma processing system,
a signal digitizer for sampling the detected light over a plurality of cycles of a RF modulation period to provide a digitized signal; and
a signal processor for deriving a local reference waveform signal for the RF modulation period from the plurality of cycles of the digitized signal and for analyzing the local reference waveform signal for the modulation period to derive a result of one of a fault condition of the pulsed plasma processing system, a process condition of the pulsed plasma processing system, and waveform parameter of the detected light, and transferring the result to the reactor control system.

12. The system of claim 11, wherein the signal processor derives local reference waveform signal for the modulation period from the plurality of cycles of the digitized signal by partitioning each modulation period of the digitized signal into a plurality of subunits of waveform intensity values, a number of subunits based on a predetermined time resolution, computing an average waveform intensity value for each of the plurality of subunits from the plurality of subunits of waveform intensity values and then compiling each of the average waveform intensity values from the respective subunits into the local reference waveform signal for the modulation period.

13. The system of claim 12, wherein the signal processor temporally correlates each of the plurality of cycles of digitized signal.

14. The system of claim 13, wherein each of the plurality of cycles of modulation period of the digitized signal is temporally correlated to one of another cycle of modulation period of the digitized signal and the predetermined pulsed modulation period produced from the RF plasma generator.

15. The system of claim 11, wherein the light detector detects instantaneous light generated by the pulsed plasma processing system; and the signal digitizer samples the instantaneous detected light to provide a digitized instantaneous waveform signal and the signal processor compares the digitized instantaneous waveform signal to the local reference waveform signal.

16. The system of claim 11, wherein the signal digitizer samples the detected light above 100-times the predetermined frequency of the RF plasma generator and the signal processor analyzes the local reference waveform signal by applying a Fourier analysis to determine at least one waveform signal parameter in the frequency domain, wherein the waveform signal parameter is one of duty cycle, Fourier component amplitudes, fundamental frequency and harmonic frequency and phase parameters.

17. The system of claim 16, wherein the signal processor transfers at least one of the digitized signal and the local reference waveform signal to the reactor control system.

18. The system of claim 17, wherein the reactor control system modifies operation of the pulsed plasma processing system based upon at least one of the digitized signal, the local reference waveform signal and at least one waveform signal parameter thereof.

19. The system of claim 15, wherein the signal processor transfers at least one of the digitized signal and the local reference waveform signal to the reactor control system.

20. The system of claim 19, the reactor control system modifies operation of the pulsed plasma processing system based upon at least one of the digitized signal, the local reference waveform signal and the comparison of the digitized instantaneous waveform signal to the local reference waveform signal.
